(19) United States
(12) Patent Application Publication
(10) Pub. No.: US 2013/0328088 A1
(43) Pub. Date: Dec. 12, 2013

(54) LED Module and Lighting Apparatus

(71) Applicant: TOSHIBA LIGHTING & TECHNOLOGY CORPORATION, Yokosuka-shi (JP)

(72) Inventor: Kazuto Morikawa, Yokosuka-shi (JP)

(21) Appl. No.: 13/833,681

(22) Filed: Mar. 15, 2013

(30) Foreign Application Priority Data
Jun. 11, 2012 (JP) 2012-131721

(51) Int. Cl. H01L 33/44

(52) U.S. Cl. CPC H01L 33/44
USPC 257/98; 257/88

(57) ABSTRACT

According to one embodiment, an LED module according to the embodiment is configured by an LED chip, a pair of wiring bodies, and sealing resin. The pair of wiring bodies are connected to both electrodes of the LED chip, respectively. The sealing resin is light-transmissive, and is provided so as to cover a top face and a base of the LED chip, and cover at least a part of the pair of wiring bodies.

### CROSS-REFERENCE TO RELATED APPLICATIONS

This application is based upon and claims the benefit of priority from the prior Japanese Patent Application No. 2012-131721, filed on Jun. 11, 2012, the entire contents of which are incorporated herein by reference.

### FIELD

Embodiments described herein relate generally to an LED module in which an LED chip as a light source is sealed with light-transmissive resin, and a lighting apparatus in which the LED module is arranged.

### BACKGROUND

In the related art, in a lighting apparatus, a COB (Chip on Board) type LED module is used in which a plurality of LED bare chips are provided in parallel on an insulating resin layer which is provided on one surface side of a metal base substrate, a frame portion which surrounds the LED bare chips is provided, light-transmissive resin such as silicone resin in which phosphor is mixed is filled in the frame portion, and each LED bare chip is embedded using the sealing resin.

That is, the LED module is used in various LED lamps such as a bulb-type LED lamp, a linear LED lamp, or a circular LED lamp, in addition to a general lighting fixture.

However, since the LED module in the related art emits radiated light of the LED bare chips from the one surface side of the substrate, for example, in a lighting fixture which is provided in a room, indirect light for illuminating a wall, or a ceiling is insufficient, and it feels that the whole room is dark.

That is, the lighting apparatus in which the LED module in the related art is used has a structure in which it is difficult to radiate illumination light in a wide range.

Therefore, an LED module which is able to radiate illumination light in a wide range, and a LED lamp in which the LED module is used are proposed. That is, an LED bare chip is arranged in a concave portion of a container which is light-transmissive, and the concave portion is enclosed by a sealing member which includes a wavelength conversion material. In addition, in order to output light to the lower part, and the side of the container, a sintered material film which converts a wavelength of light which is radiated from the LED bare chip to a predetermined wavelength is formed on the rear surface of the container. And if desired, a groove is formed in the periphery of the rear surface of the container so as to surround the sintered material film, and the wavelength conversion material is accommodated.

### BRIEF DESCRIPTION OF THE DRAWINGS

FIG. 1 is a schematic top view of an LED module according to a first embodiment.

FIG. 2 is a schematic cross-sectional view of the LED module in the A-A arrow direction.

FIG. 3 is an enlarged schematic cross-sectional view of a B part.

FIG. 4 is a schematic perspective view of an LED module according to a second embodiment.

FIGS. 5A to 5D are explanatory diagrams which illustrate a manufacturing process of the LED module.

FIGS. 6A and 6B are explanatory diagrams which illustrate a connecting method of an LED chip.

FIG. 7 is a schematic perspective view of an LED module according to a third embodiment.

FIGS. 8A and 8B are explanatory diagrams which illustrate another radiating structure.

FIG. 9 is a schematic cross-sectional side view of a lighting apparatus according to a fourth embodiment.

FIG. 10 is a schematic side view in which a part of another lighting system is cut out.

### DETAILED DESCRIPTION

In view of the above circumstances, there are provided an LED module which outputs light at least to the top face side, and the lower surface side of an LED chip, of which a configuration is simple, and productivity is good, and a lighting apparatus in which the LED module is included.

An LED module according to the embodiment is configured by including an LED chip, a pair of wiring bodies, and sealing resin.

The pair of wiring bodies are connected to both electrodes of the LED chip, respectively. The sealing resin is light-transmissive, which is transparent or semitransparent, covers a top surface and an undersurface of the LED chip, and is provided so as to cover at least a part of the pair of wiring bodies.

According to the embodiment, since the sealing resin covers the top surface and the undersurface of the LED chip, light which is radiated from the LED chip is expected to pass through the sealing resin, and to be output to each direction of the top surface side, the lower surface side, and the side surface side of the LED chip. In addition, since the top surface and the undersurface of the LED chip is covered with the sealing resin, it is possible to expect to manufacture the LED module easily, not using a complicated configuration.

Hereinafter, the embodiments will be described with reference to drawings. First, a first embodiment will be described.

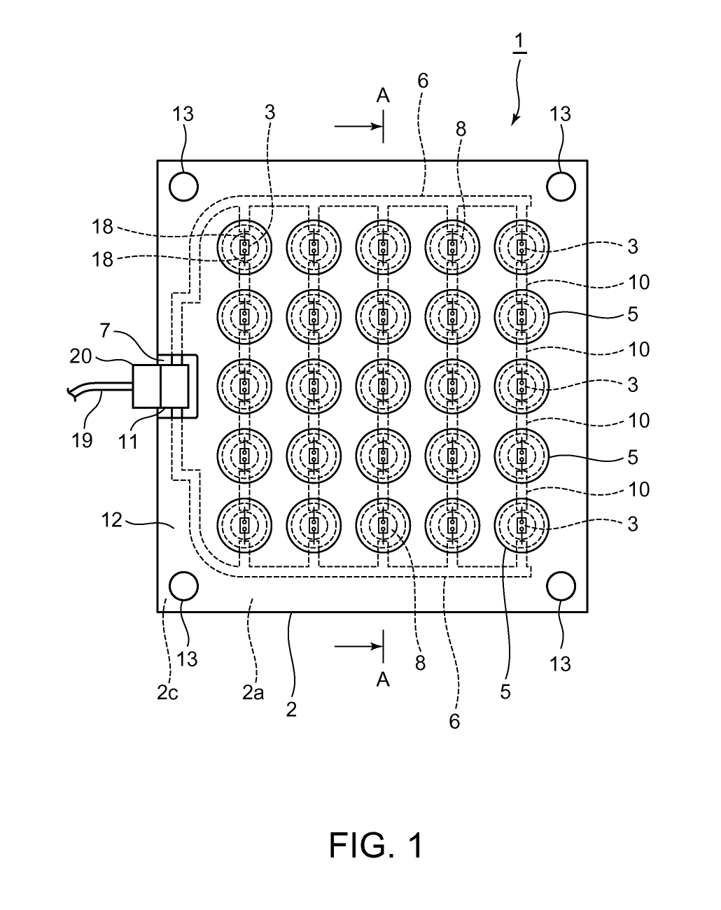

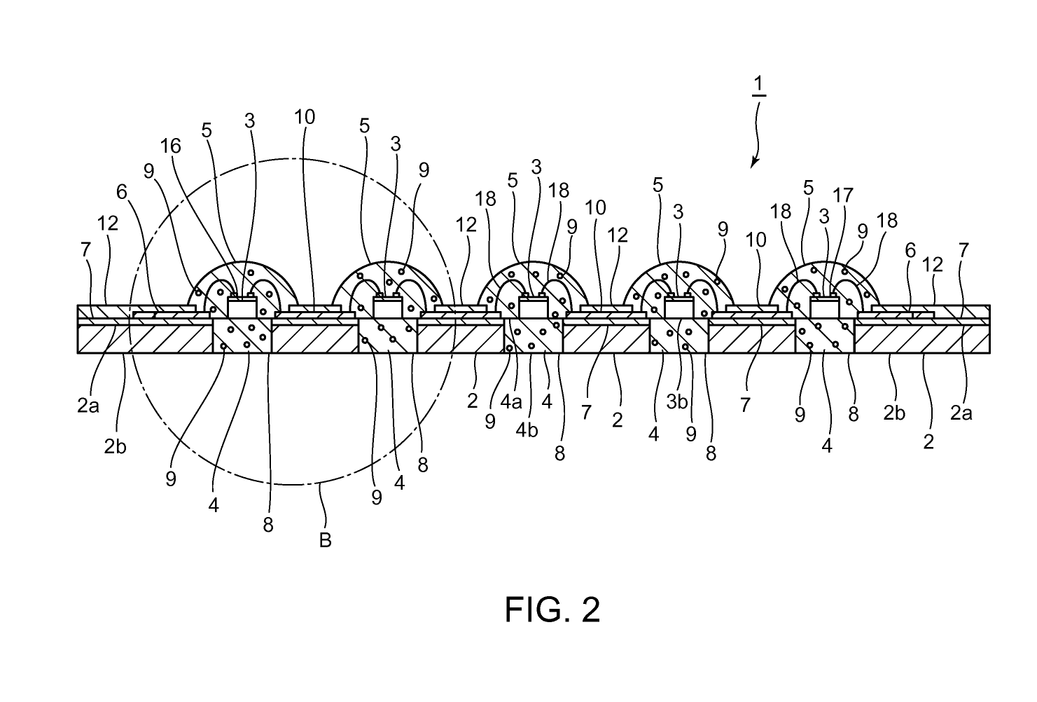

An LED module 1 according to the embodiment is configured as illustrated in FIGS. 1 and 2. In FIGS. 1 and 2, the LED module 1 is configured by including a substrate 2, LED chips 3, sealing resins 4 and 5, and a pair of wiring bodies 6 and 6.

The substrate 2 is formed, for example, of plate-shaped aluminum (Al) of which the thickness is 1.2 mm which is formed in a square shape, and an insulating layer 7 of which the thickness is, for example, 80 μm is formed on one surface 2a thereof. The substrate 2 is hardly broken compared to a light-transmissive material. The insulating layer 7 is formed of, for example, an epoxy material, and an inorganic filler material, and has high thermal conductivity.

In addition, the substrate 2 is formed with through holes 8 which are formed from the surface of the insulating layer 7 to the other surface 2b. The through hole 8 is formed in a circular shape which is larger than an undersurface 3b of the LED chip 3. In addition, as illustrated in FIG. 1, the through holes 8 are formed in matrix with a predetermined gap on the substrate 2. According to the embodiment, five lines of through holes 8 are provided by aligning five through holes 8 in a line.

As illustrated in FIG. 2, the sealing resin 4 is provided at the through hole 8. The sealing resin 4 is formed, for example, of translucent silicone resin, which is light-transmissive, namely, transparent or semitransparent, is filled in the through hole 8 so as to be flush with the surface of the insulating layer 7, and the other surface 2b of the substrate 2, respectively. That is, a top surface 4a and an undersurface 4b of the sealing resin 4 have planar shapes, respectively.

The sealing resin 4 contains a YAG phosphor 9 as phosphor of a predetermined concentration. When blue light radiated from the LED chip 3 which will be described later is input, the YAG phosphor 9 converts a wavelength of the blue light to that of yellow light. That is, the YAG phosphor 9 performs a wavelength conversion with respect to part of radiated light of the LED chip 3. The yellow light which is performed with the wavelength conversion is mixed with the blue light which is radiated from the LED chip 3, and is output to the outside from the undersurface 4b of the sealing resin 4. In this manner, it is viewed as if white light is radiated from the through hole 8 on the other surface 2b side of the substrate 2.

Besides, the undersurface 4b of the sealing resin 4 does not necessarily have to be a planar shape, and may be provided so as to overflow to the other surface 2b of the substrate 2. In addition, the through hole 8 may be formed to be smaller than the undersurface 3b of the LED chip 3 so that a part of the undersurface 3b of the LED chip 3 faces the sealing resin. In addition, the substrate 2 may be an opaque synthetic resin plate, or a ceramic plate without being limited to a metal plate.

In addition, the pair of wiring bodies 6 and 6 are formed on both end sides of the five through holes 8 which are aligned on the insulating layer 7 of the substrate 2. In addition, an intermediate wiring body 10 is formed between the through holes 8 and 8. The pair of wiring bodies 6 and 6 and the intermediate wiring body 10 are formed of a conductive material in which, for example, a metal layer of copper (Cu) of which the thickness is 10 μm, for example, and nickel (Ni) is plated on the surface of the copper (Cu), and further, silver (Ag) is plated thereon, and are formed having the appropriate width and full length, respectively.

In FIG. 1, a wiring connector 11 is provided at one end portion 2c side of the surface 2a of the substrate 2. The wiring connector 11 is electrically connected to the pair of wiring bodies 6 and 6. In addition, a white resist 12 having electric insulation is applied onto the insulating layer 7 excepting for a part of the pair of wiring bodies 6 and 6, a part of the intermediate wiring body 10, and a part of the wiring connector 11, respectively. In addition, attaching holes 13 of the LED module 1 are provided at squared four corners of the substrate 2.

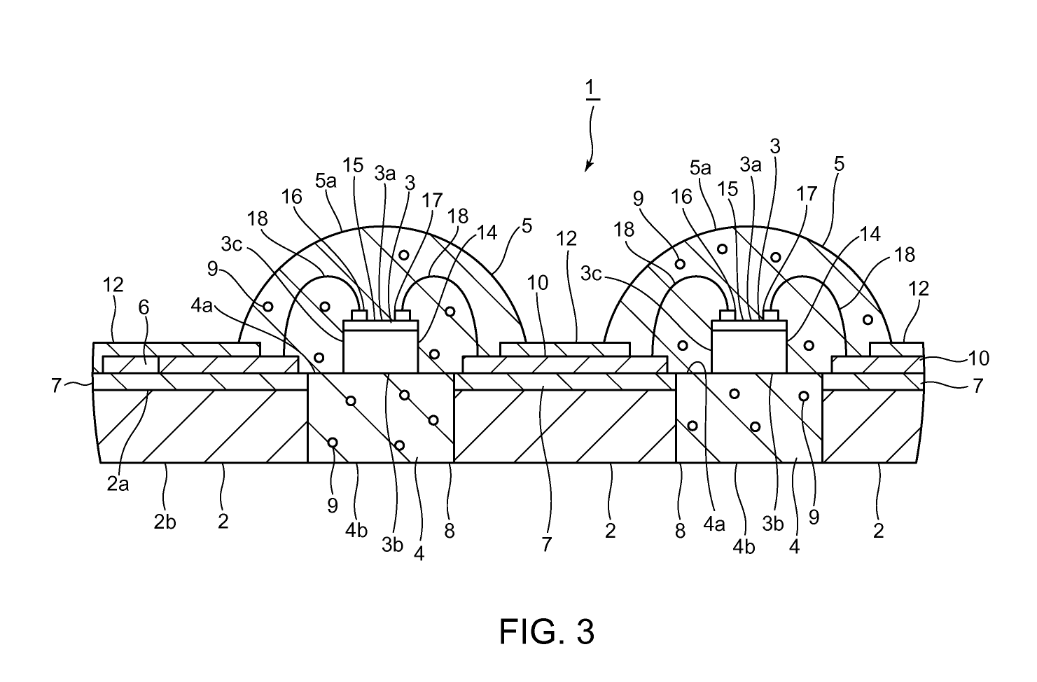

The LED chip 3 is formed by a plurality of chips, and is formed on the one surface 2a side of the substrate 2. As illustrated in FIG. 3, in the LED chip 3, a light emitting layer 15 is formed on the surface of a sapphire 14 which is formed as a rectangular body, and electrodes 16 and 17 are formed on the surface of the light emitting layer 15. The sapphire 14 is adhered to the top face 4a of the sealing resin 4 using transparent silicone which is not shown. In this manner, the whole undersurface 3b of the LED chip 3 is covered with the sealing resin 4, and the LED chip faces the through hole 8 of the substrate 2.

In addition, the light emitting layer 15 is formed by including a light emitting material, for example, InGaN which radiates light in a range from ultraviolet light to blue light and radiates blue light when being electrically connected. Since the sapphire 14 is transparent, the blue light which is radiated from the light emitting layer 15 is also output to the through hole 8 side of the substrate 2, and is input into the sealing resin 4 from the top face 4a of the sealing resin 4.

The electrodes 16 and 17 are respectively wire bonded to the neighboring intermediate wiring bodies 10 which are lined. In addition, as illustrated in FIG. 2, the electrode 16 of the LED chip 3 on the leftmost end in the figure is wire bonded to one of the pair of wiring bodies 6 and 6, and the electrode 17 of the LED chip 3 on the rightmost end in the figure is wire bonded to the other of the pair of wiring bodies 6 and 6. That is, as illustrated in FIG. 1, the plurality of LED chips 3 are connected in series by bonding wires 18 and the intermediate wiring bodies 10 in each line, and are electrically connected to the pair of wiring bodies 6 and 6.

The wiring connector 11 is connected to the LED chips 3 which are connected in series and in parallel through the pair of wiring bodies 6 and 6. The wiring connector 11 is connected with a wiring connector 20 which is connected with an electric wire 19. The electric wire 19 is connected to a not shown power supply unit which supplies power to the LED chip 3 from the outside.

Besides, the substrate 2 may be provided with a terminal block, a terminal to which the electric wire 19 is soldered, or the like, instead of the wiring connector 11.

In FIG. 3, the LED chip 3 is covered with the sealing resin 5 which is provided on the one surface 2a side of the substrate 2. The sealing resin 5 is provided, for example, by being dropped on the top surface 3a of the LED chip 3 from the upper side of the substrate 2 so as to cover the top surface 3a of the LED chip 3, and a part of the pair of wiring bodies 6 and 6, and a part of the intermediate wiring body 10, respectively. In addition, the sealing resin is formed in a dome shape on the resist 12 through natural curing, or heat curing using a dryer or the like. That is, the sealing resin 5 covers the though hole 8 of the substrate 2 (top surface 4a of sealing resin 4) and the LED chip 3, and embeds the bonding wire 18.

According to the embodiment, the sealing resin 5 is formed using the same material as that in the sealing resin 4. That is, the sealing resin 5 is formed of, for example, light-transmissive silicone resin, and contains the YAG phosphor 9 as the phosphor of predetermined concentration. In the sealing resin 5, part of the blue light which is radiated from the LED chip 3 is converted to yellow light through wavelength conversion using the YAG phosphor 9, and is output to the outside on the one surface 2a side of the substrate 2 from a surface 5a of the sealing resin 5 after the yellow light and blue light are mixed. In this manner, it is viewed as if white light is radiated from the one surface 2a side of the substrate 2.

In the LED chip 3, the top surface 3a, the undersurface 3b, and an outer peripheral side surface 3c are covered with the sealing resins 4 and 5 by being in contact therewith. That is, the whole LED chip 3 is covered with the sealing resins 4 and 5.

Besides, the sealing resins 4 and 5 are not limited to the heat curing resin, and may be photo curing resin which is cured by photo-irradiation of ultraviolet light, or the like.

Subsequently, operations of the embodiment will be described.

When the wiring connector 11 of the LED module 1 is supplied with power through the electric wire 19 from the power supply unit, a predetermined current flows in the LED chip 3. The LED chip 3 emits heat, and blue light is radiated from the light emitting layer 15. Most of the blue light is input into the sealing resin 5, apart thereof passes through the sapphire 14, and is input into the sealing resin 4. The blue light and the yellow light which pass through the sealing resin 5 are input into the sealing resin 4 from the sealing resin 5 side, as well.

Part of the blue light which is input into the sealing resin 5 from the light emitting layer 15 is output to the outside from the surface 5a of the sealing resin 5 by passing through the sealing resin 5, part thereof is converted to yellow light through wavelength conversion using the YAG phosphor 9, and is output to outside from the surface 5a of the sealing resin 5. The blue light and the yellow light which are output from the surface 5a of the sealing resin 5 become white light by being mixed. The white light is radiated from the one surface 2a side of the substrate 2. The white light is radiated to the front and the side on the one surface 2a side of the substrate 2.

In addition, in the blue light which is input into the sealing resin 4, part thereof is output to the outside from the undersurface 4b of the sealing resin 4 by passing through the sealing resin 4, and part thereof is output to the outside from the undersurface 4b of the sealing resin 4 by being converted to yellow light through wavelength conversion using the YAG phosphor 9. The blue light and the yellow light which are output from the undersurface 4b of the sealing resin 4 are mixed, and become white light. The white light is radiated from the through hole 8 on the other surface 2b of the substrate 2. That is, the white light is radiated to the rear side on the other surface 2b side of the substrate 2.

In this manner, the white light beams are radiated from the one surface 2a side, and the other surface 2b side of the substrate 2, respectively. In addition, since the sealing resins 4 and 5 can be formed using the same material, the white light beams which are output from the one surface 2a side, and the other surface 2b side of the substrate 2 have approximately the same color tone, and unevenness in the color tone is suppressed. In addition, the substrate 2 is formed by an opaque metal plate, and the blue light which passes through the substrate 2 is not output from the substrate 2 itself, it is possible to prevent the color tone of the white light which is output from the other surface 2b side of the substrate 2 from being changed.

In addition, since it is possible to cover the whole LED chip 3 along with the sealing resin 5 by providing the sealing resin 4 in the through hole 8 of the substrate 2, it is possible to easily, and inexpensively manufacture the LED module 1 which is able to output radiated light to the front, the side, and the rear side of the substrate 2.

In addition, heat which is generated in the LED chip 3 is conducted to the sealing resins 4 and 5, is conducted to the substrate 2 from the sealing resin 4, and is radiated to the outer space from the sealing resins 4 and 5, and the substrate 2.

In the LED module 1 according to the embodiment, the sealing resin 4 is provided at the through hole 8 which is formed in the opaque substrate 2, and is provided on the one surface 2a side of the substrate 2 so that the undersurface 3b of the LED chip 3 faces the through hole 8, it is possible to cover the whole LED module 1 using the sealing resins 4 and 5, to output the radiated light to the front, the side, and the rear side of the substrate 2, and to suppress the unevenness in the color tone of the output light. In addition, since the top surface 3a and the undersurface 3b of the LED chip 3 are covered with the sealing resins 4 and 5, the configuration of the LED module 1 is not complicated, and due to this, it is possible to easily and inexpensively manufacture the LED module 1.

Besides, according to the embodiment, in the LED module 1, the LED chips 3 are formed in five lines by arranging five chips in one line, however, it is not limited to this, and the desired number, and number of lines of the LED chips 3 can be provided.

Subsequently, a second embodiment will be described.

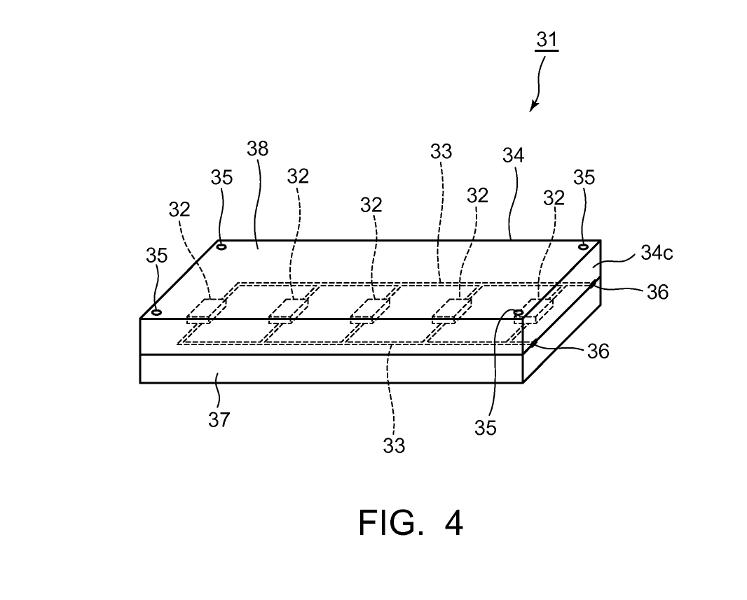

An LED module 31 according to the second embodiment is configured as illustrated in FIGS. 4 to 6. Besides, the same portions, and portions corresponding to the same portions as those in FIGS. 1 and 2 are given the same reference numerals, and descriptions thereof will be omitted.

In FIG. 4, the LED module 31 is formed by including an LED chip 32, a pair of wiring bodies 33 and 33, and a sealing resin 34. The LED chip 32 is formed to be the same as the LED chip 3 which is described in FIG. 3, and radiates blue light. The pair of wiring bodies 33 and 33 are formed to be similar to the pair of wiring bodies 6 and 6 which are described in FIGS. 1 and 2 excepting for a difference in a wiring pattern. In addition, the LED chip 32 and the pair of wiring bodies 33 and 33 are embedded in the sealing resin 34.

The sealing resin 34 is formed as a rectangular body, is formed of, for example, translucent silicone resin, which is light-transmissive, similarly to the sealing resins 4 and 5 which are described in FIG. 3, and contains a YAG phosphor 9 (not shown) as a phosphor of a predetermined concentration. Four corners of the sealing resin 34 are provided with attaching holes 35 of the LED module 31. In addition, on one side of side surfaces 34c of the sealing resin 34 is provided with a pair of connection terminals 36 and 36. The pair of connection terminals 36 and 36 are electrically connected to the pair of wiring bodies 33 and 33, respectively. The pair of connection terminals 36 and 36 are connected with an electric wire 19 (not shown) from a power supply unit using, for example, soldering.

In addition, the sealing resin 34 is formed in a first sealing resin portion 37, and a second sealing resin portion 38. The first and second sealing resin portions 37 and 38 are formed in rectangular shapes, respectively.

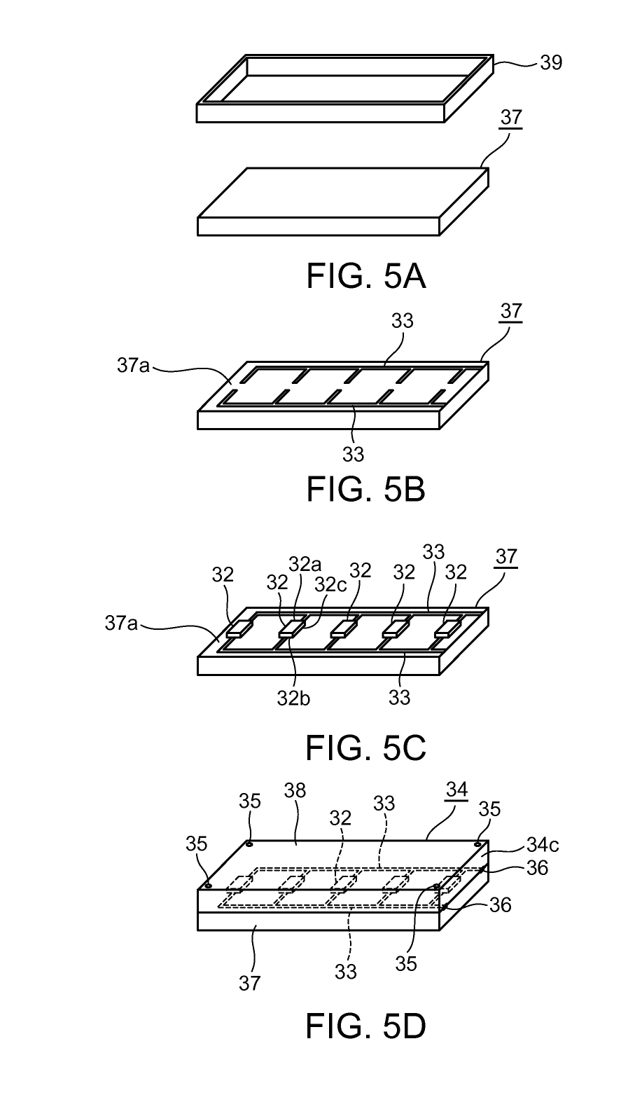

The LED module 31 is manufactured as illustrated in FIGS. 5A to 5D. First, as illustrated in FIG. 5A, the first sealing resin portion 37 is manufactured. In the first sealing resin portion 37, light-transmissive resin in which the YAG phosphor 9 of a predetermined concentration is included, for example, silicone resin is filled in a rectangular frame body 39 which is provided on a plane, and is cured. The silicon resin is cured, and then the frame body 39 is detached, thereby forming the first sealing resin portion 37.

In addition, as illustrated in FIG. 5B, the pair of wiring bodies 33 and 33 are formed by being printed on a surface 37a of the first sealing resin portion 37. Besides, the pair of wiring bodies 33 and 33 which are formed in advance may be built on the surface 37a of the first sealing resin portion 37.

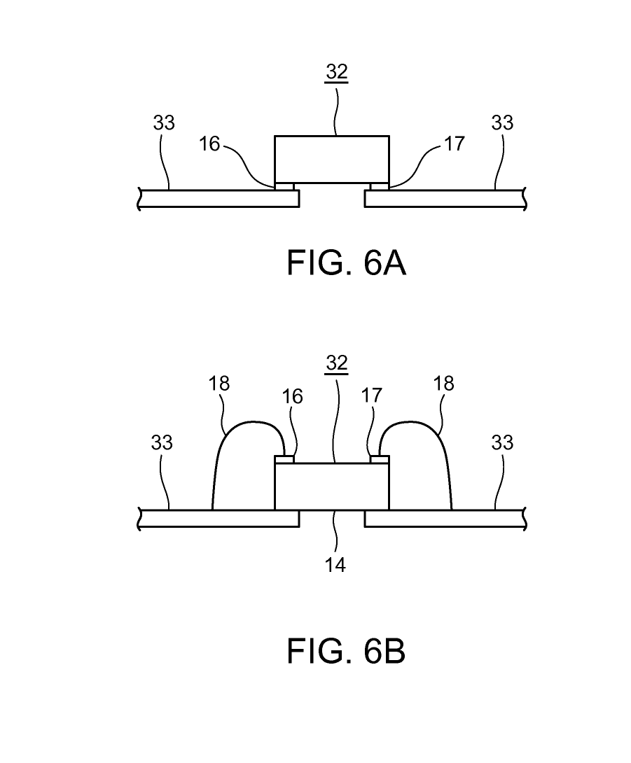

In addition, as illustrated in FIG. 5C, the LED chip 32 is mounted on the pair of wiring bodies 33 and 33. Here, as illustrated in FIG. 6A, in the LED chip 32, electrodes 16 and 17 thereof are directly attached to the pair of wiring bodies 33 and 33. The electrodes 16 and 17 are connected to the pair of wiring bodies 33 and 33, for example, by an adhesive having conductivity, and thermal conductivity. That is, the LED chip 32 is provided so as to come into contact with the pair of wiring bodies 33 and 33.

In addition, as illustrated in FIG. 6B, in the LED chip 32, a sapphire substrate 14 thereof is provided so as to come into contact with the pair of wiring bodies 33 and 33, and the electrodes 16 and 17 may be connected to the pair of wiring bodies 33 and 33 through bonding wires 18 and 18. The sapphire 14 is attached to the pair of wiring bodies 33 and 33 using, for example, an adhesive having thermal conductivity.

In addition, in FIG. 5C, one LED chip 32 is provided between the pair of wiring bodies 33 and 33, however, when providing the plurality of LED chips, in FIG. 5B, an intermediate wiring body 10 is formed between the pair of wiring bodies 33 and 33. Then, in FIG. 5C, the LED chips 32 are provided between the wiring body 33 and the intermediate wiring body 10, and between the intermediate wiring bodies 10 and 10.

In this manner, the pair of wiring bodies 33 and 33, and the LED chip 32 are provided on the surface 37a of the first sealing resin portion 37. In addition, a frame body (not shown) which comes into close contact with the periphery of the first sealing resin portion 37, and protrudes from the surface 37a of the first sealing resin portion 37 by predetermined length is provided. In the frame body, silicone resin which is the same as the first sealing resin portion 37 is filled. By curing the silicone resin, the second sealing resin portion 38 is formed. The second sealing resin portion 38 comes into contact with a top surface 32a, an undersurface 32b, and a side surface 32c of the LED chip 32, that is, comes into contact with the whole LED chip 32, and covers thereof. In this manner, the second sealing resin portion 38 is provided so that the LED chip 32 and the pair of wiring bodies 33 and 33 are embedded on the surface 37a of the first sealing resin portion 37.

In addition, as illustrated in FIG. 5D, the sealing resin 34 is formed by detaching the frame body after forming the second sealing resin portion 38. In addition, the pair of connection terminals 36 and 36 are attached to the side surface 34c of the sealing resin 34. The pair of connection terminals 36 and 36 are attached so as to be electrically connected to the pair of wiring bodies 33 and 33 which are exposed to the surface 34c of the sealing resin 34, respectively. In addition, the attaching holes 35 are formed on four corner sides of the sealing resin 34. In this manner, the LED module 31 is formed.

The LED module 31 can be attached to an apparatus main body of a lighting apparatus by holding the four corner portions of the sealing resin 34, for example. In this case, the attaching holes 35 may not be provided in the sealing resin 34. In addition, a wiring connector may be provided instead of the pair of connection terminals 36 and 36.

In the LED module 31, the whole LED chip 32 is covered with the sealing resin 34 which is formed by the first sealing resin portion 37 and the second sealing resin portion 38, and the whole sealing resin 34 is exposed to the outer space. Accordingly, white light is output from the LED module 31 in a wide range. In addition, since the first sealing resin portion 37 and the second sealing resin portion 38 are formed using the same light-transmissive resin (silicone resin), the phosphor (YAG phosphor 9), and the concentration, unevenness in a color tone of the white light which is output from the LED module 31 is suppressed.

In addition, since it is a configuration in which the whole LED chip 32 is covered with the sealing resin 34 by forming the first sealing resin portion 37 and the second sealing resin portion 38, it is possible to manufacture the LED module 31 easily, accordingly, productivity is good, and it is possible to form the LED module 31 which outputs the radiated light in a wide range at low cost.

In addition, heat which is generated in the LED chip 32 is conducted to the sealing resin 34, and is radiated to the outer space from the sealing resin 34.

In the LED module 31 according to the embodiment, since the module has a configuration in which the whole LED chip 32 is covered with the sealing resin 34 which is formed by the first sealing resin portion 37 and the second sealing resin portion 38, it is possible to manufacture the LED module 31 easily and inexpensively, to output the radiated light in a wide range of the sealing resin 34, and to suppress the unevenness in the color tone of the radiated light.

Besides, according to the embodiment, the LED chip 32 is provided so as to come into contact with the wiring bodies 33 and 33, however, the chip may be mounted on the surface 37a of the first sealing resin portion 37. In this case, the electrodes 16 and 17 of the LED chip 32 are wire bonded to the pair of wiring bodies 33 and 33, respectively.

Subsequently, a third embodiment will be described.

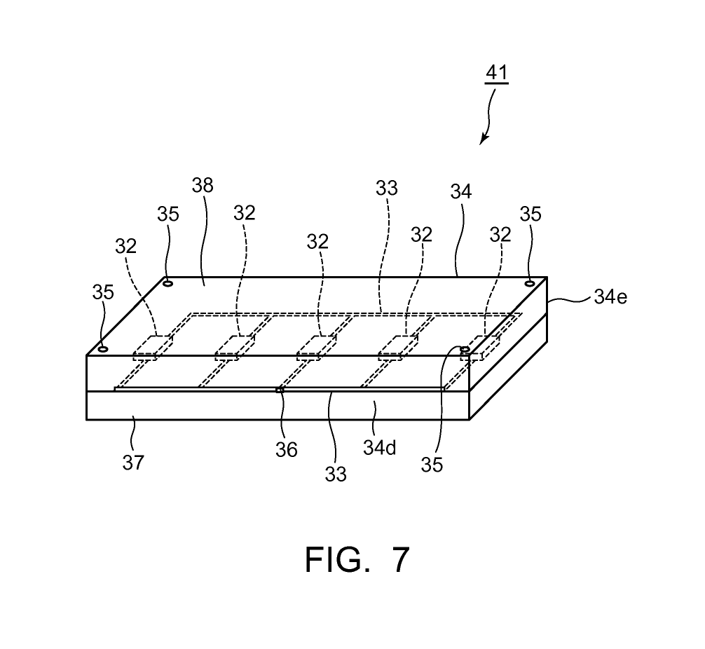

An LED module 41 according to the third embodiment is configured as illustrated in FIG. 7. Besids, the same portions and portions corresponding to the same portions as those in FIG. 4 are given the same reference numerals, and descriptions thereof will be omitted.

The LED module 41 is a module in which the pair of wiring bodies 33 and 33 in the LED module 31 which is illustrated in FIG. 4 are provided so as to expose to a front surface 34d and a rear surface 34e of the sealing resin 34, respectively. In addition, the connection terminals 36 are provided to the front surface 34d and the rear surface 34e of the sealing resin 34, respectively.

The heat which is generated in the LED chip 32 is conducted to the sealing resin 34, and is conducted to the pair of wiring bodies 33 and 33 with which the LED chip 32 is in contact. Since the pair of wiring bodies 33 and 33 are formed of metal, the heat generated in the LED chip 32 is rapidly transferred to the front surface 34d and the rear surface 34e of the sealing resin 34. In addition, the heat is radiated to the outer space from the exposed portion of the pair of wiring bodies 33 and 33.

In the LED module 41 according to the embodiment, since the heat which is generated in the LED chip 32 is conducted through the pair of wiring bodies 33 and 33, and is radiated to the outer space from the exposed portions of the pair of wiring bodies 33 and 33, it is possible to suppress a temperature increase in the sealing resin 34 and the LED chip 32, respectively.

Besides, in the LED module 41, the exposed portions of the pair of wiring bodies 33 and 33 may be thinly covered with an insulating protection film or resin having high thermal conductivity.

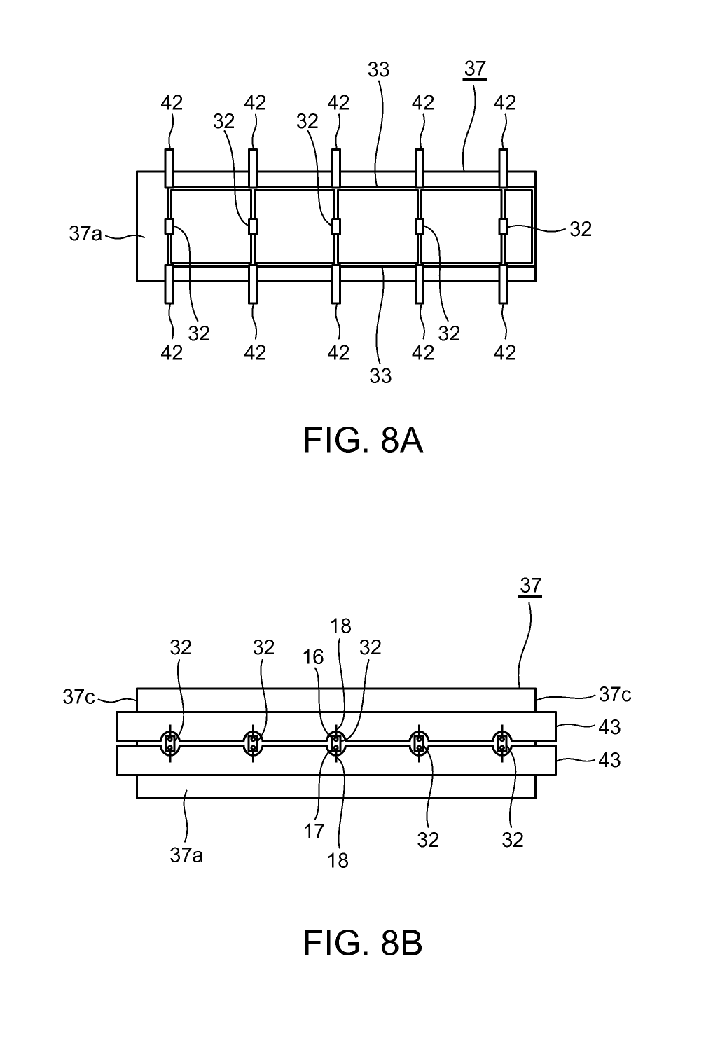

In addition, as illustrated in FIG. 8A, radiating bodies, which is thermal radiation bodies, 42 may be provided so as to protrude from the front surface 34d and the rear surface 34e of the sealing resin 34, respectively, without exposing the pair of wiring bodies 33 and 33 to the front surface 34d and the rear surface 34e of the sealing resin 34, respectively. The radiating body 42 is formed, for example, in a rectangular plate shape, and is attached to the pair of wiring bodies 33 and 33 using a thermal conductive adhesive on the surface 37a of the first sealing resin portion 37.

In the radiating body 42, metal having high thermal conductivity, for example, aluminum (Al), or synthetic resin, for example, polybuthylene telethaphlate (PBT) resin is used. Since the electrode portion is not exposed to the outer surface of the sealing resin 34, it is preferable that the radiating body 42 be formed using synthetic resin having high thermal conductivity, and electric insulation. When using metal, the protruding portion may be coated using a protection film having thermal conductivity, and electric insulation.

When the radiating body 42 is included, the heat which is generated in the LED chip 32 is conducted to the radiating body 42 from the pair of wiring bodies 33 and 33, and is radiated from the protruding portion in the outer space, it is possible to suppress the temperature increase in the respective sealing resin 34 and the LED chip 32.

In addition, as illustrated in FIG. 8B, the LED chip 32, and a pair of wiring bodies 43 and 43 may be provided on the surface 37a of the first sealing resin portion 37, respectively. The pair of wiring bodies 43 and 43 are formed in an approximately rectangular shape, respectively, and are provided so as to protrude to the outside from both side surfaces 37c and 37c of the first sealing resin portion 37. The pair of wiring bodies 43 and 43 are formed of a conductive material, for example, a copper plate with a predetermined thickness of, for example, 1 mm, and nickel (Ni) is plated on the surface of the copper plate, and further, silver is plated thereon.

The electrodes 16 and 17 of the LED chip 32 are connected to the pair of wiring bodies 43 and 43 by the bonding wires 18, respectively. Protrusion portions of the pair of wiring bodies 43 and 43 are connected to an electric wire 19 (not shown) which is derived from the power supply unit.

The heat which is generated in the LED chip 32 is conducted to the sealing resin 34, and is conducted to the pair of wiring bodies 43 and 43 from the sealing resin 34. Since the pair of wiring bodies 43 and 43 are formed of metal, the heat is rapidly transferred, and is radiated from the protrusion portions in the outer space. In this manner, it is possible to suppress the temperature increase in the sealing resin 34 and the LED chip 32, respectively.

Subsequently, a fourth embodiment will be described.

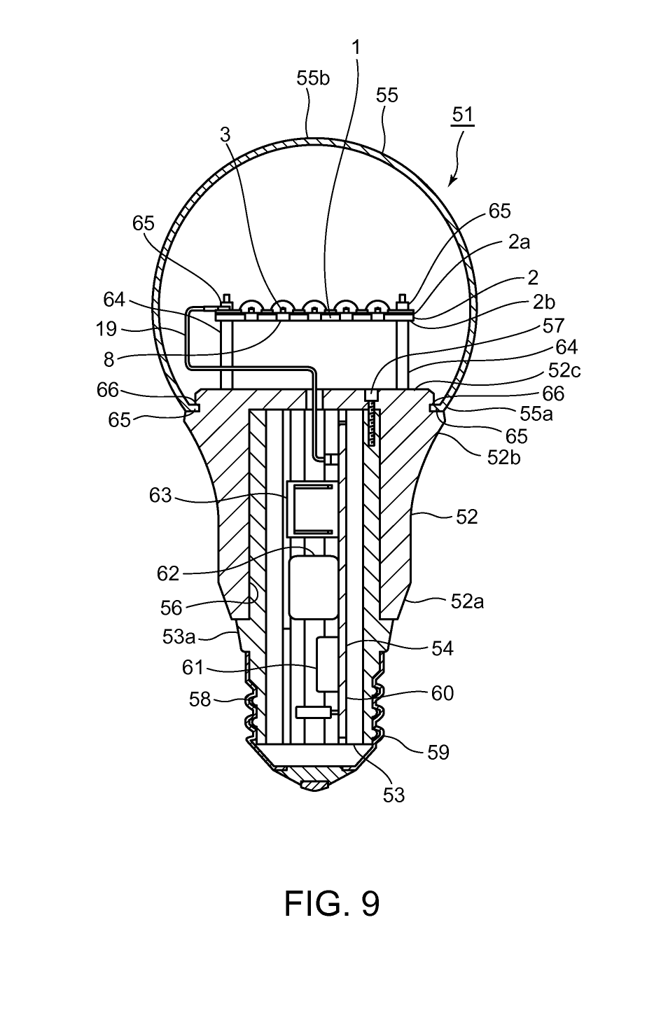

A lighting apparatus 51 according to the embodiment is an LED light bulb which can be attached to and detached from a socket for electric light bulb, and is configured as illustrated in FIG. 9. Besides, the same portions as those in FIG. 1 are given the same reference numerals, and descriptions thereof will be omitted.

The lighting apparatus 51 is configured by including the LED module 1 which is illustrated in FIG. 1, an envelope 52, an attaching body 53, a power supply unit 54, and a globe 55.

The envelope 52 is formed of a metal material having high thermal conductivity, for example, aluminum (Al), is formed in a pillar shape where a diameter is gently increased from one end side 52a to the other end side 52b, and an insertion hole 56 is formed in a columnar shape with predetermined depth from the one end side 52a to the other end side 52b in a center axis portion thereof. In addition, in the envelop 52, an end surface 52c of the other end side 52b is formed as a plane.

The attaching body 53 is inserted into the insertion hole 56 of the envelope 52, and is attached to the envelope 52 using a screw 57. The attaching body 53 is formed in an approximately cylinder shape which comes into close contact with a wall face of the insertion hole 56 using, for example, polybuthylene telethaphlate (PBT) resin, and has electric insulation.

In addition, in the attaching body 53, a projection 58 is formed in a spiral shape on the outer surface of one end side 53a thereof, and a base 59 is screwed to the projection 58. The base 59 is fixed onto the outer surface of the one end side 53a of the attaching body 53 by being crimped. The base 59 can be connected to a socket for general electric light bulb for lighting of, for example, E-26 type.

The power supply unit 54 is accommodated in the attaching body 53. In addition, the power supply unit 54 is formed by including a circuit board 60, and a circuit component 61 which is mounted on the circuit board 60. The circuit component 61 is formed by a plurality of electronic components 62, a transformer 63, or the like, and configures a circuit which lights up the LED chip 3. The circuit board 60 is formed of a synthetic resin plate such as a glass epoxy material, or a metal plate such as aluminum (Al), and is formed in an approximately rectangular shape. When it is a metal plate, an insulating layer is formed, and the circuit component 61 is mounted thereon. An input side of the power supply unit 54 is connected to the base 59 through a lead wire (input line) which is not shown, and an output side thereof is connected to the LED module 1 through the electric wire 19.

The LED module 1 is provided so as to be separated from the end surface 52c of the envelope 52 by a predetermined distance. That is, the end surface 52c of the envelope 52 is provided with four (two in figure) stepped statvolts 64 as support members. The statvolts 64 are inserted into the attaching holes 13 (not shown) of the LED module 1. At this time, the other surface 2b of the substrate 2 faces the end surface 52c of the envelope 52. In addition, nuts 65 are tightened to the statvolt 64. In this manner, the LED module 1 is attached to the envelope 52 through the four statvolts 64.

The globe 55 is formed of a translucent resin material, which is light-transmissive. Here, in the globe, the other end side 55b is closed by polycarbonate (PC) resin, for example, and one end side 55a is open, and the globe is formed in an approximately spherical shape so as to cover the LED module 1. In addition, in the globe 55, a locking portion 65 on the one end side 55a is locked at a portion to be locked 66 on the other end side 52b of the envelope 52, and the globe is attached to the envelope 52.

Radiated light which is radiated from the one surface 2a side of the substrate 2 of the LED module 1 passes through the globe 55, and is output to the front side and the side of the globe 55. In addition, the radiated light which is radiated from the through hole 8 on the other surface 2b of the substrate 2 is reflected on the end surface 52c of the envelope 52, transmits the one end side 55a of the globe 55, and is output to a space on the envelope 52 (base 59) side. Since the globe 55 transmits the radiated light from the one surface 2a side and the other surface 2b side of the substrate 2, it seems as if the whole globe shines.

In the lighting apparatus (LED light bulb) 51 according to the embodiment, since it seems as if the whole globe 55 shines, and the radiated light is also output to the base 59 side, it is possible to suppress glare, or uneven brightness in the globe 55, and to obtain an effect of suppressing a sense of unease when looking up the lighting apparatus 51. In addition, since the lighting apparatus 51 includes the LED module 1 of which production characteristics are good, and which can be formed at low cost, it is possible to manufacture the lighting apparatus at low cost.

In addition, the lighting apparatus (LED light bulb) 51 may adopt the LED module 31 which is illustrated in FIG. 4, and can obtain the same operations and effects as those which are described above.

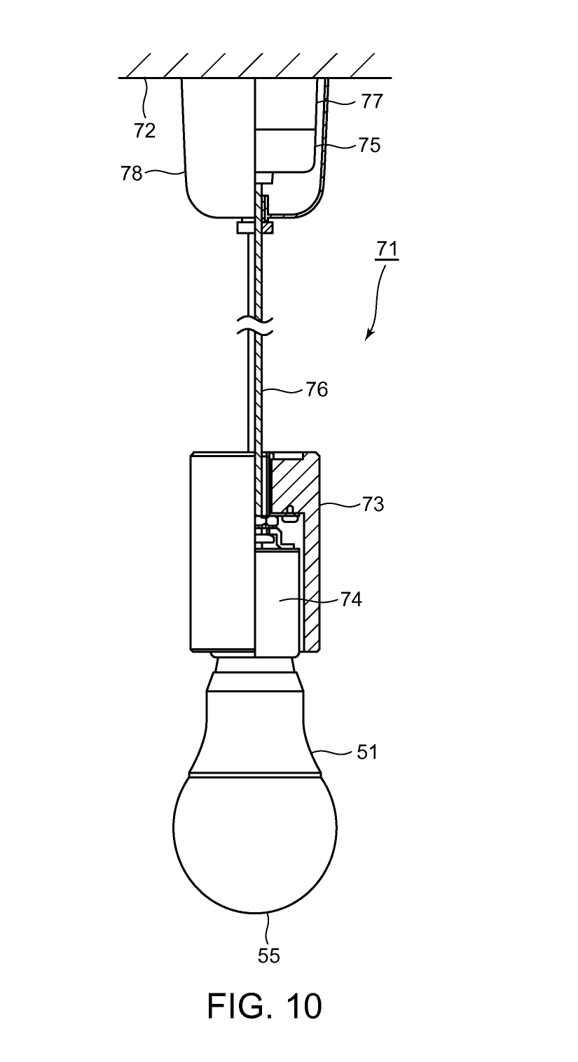

In addition, the lighting apparatus (LED light bulb) 51 is mounted, for example, on a lighting apparatus (lighting fixture) 71 which is illustrated in FIG. 10.

The lighting fixture 71 is a suspended lighting fixture which is suspended from a ceiling 72, and in which a socket for electric light bulb 74 to which the base 59 (not shown) of the lighting apparatus (LED light bulb) 51 which is illustrated in FIG. 9 is attached is arranged in a fixture main body 73 as an apparatus main body of which an outer shape is a cylindrical shape with a base. The fixture main body 73 is connected with a power code 76 having a ceiling hook cap 75 at a tip end thereof.

In addition, the ceiling hook cap 75 is attached to a ceiling hook body 77 which is arranged on the ceiling 72. In this manner, the socket for electric light bulb 74 is supplied with external power source through the power code 76, or the like. The ceiling hook cap 75, and the ceiling hook body 77 are covered with a ceiling cover 78. In addition, the lighting apparatus (LED light bulb) 51 is mounted on the socket for electric light bulb 74.

The lighting apparatus (LED light bulb) 51 is lit up according to an ON-OFF operation of a wall switch which is not shown. In addition, radiated light (white light) which is radiated from the globe 55 illuminates the floor side, and illuminates the ceiling 72 side.

The lighting fixture 71 according to the embodiment has an effect of not giving a sense of darkness in a room which is arranged with the lighting fixture 71 since the radiated light from the lighting apparatus (LED light bulb) 51 illuminates the floor side, and illuminates the ceiling 72 side, respectively. In addition, since the lighting fixture includes the lighting apparatus (LED light bulb) 51 which is formed at low cost, it is possible to reduce running cost.

In addition, the lighting apparatus (LED light bulb) 51 is not limited to the suspended lighting fixture, and is also used in a recessed lighting fixture such as a downlight, or a lighting fixture of a direct attaching type, or the like.

In addition, according to the embodiment, the LED light bulb is described as the lighting apparatus, however, it is not limited to this, and the lighting apparatus may include an apparatus main body in which the LED modules 1, 31, and 41 according to the embodiments are arranged, and a power supply unit such as the power supply unit 54.

While certain embodiments have been described, these embodiments have been presented by way of example only, and are not intended to limit the scope of the inventions. Indeed, the novel embodiments described herein may be embodied in a variety of other forms; furthermore, various omissions substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An LED module comprising:
an LED chip:
a pair of wiring bodies which are connected to both electrodes of the LED chip, respectively; and
light-transmissive sealing resin which covers a top surface and an undersurface of the LED chip, and covers at least a part of the pair of wiring bodies.

2. The module according to claim 1, further comprising an opaque substrate including a through hole,
wherein the LED chip is provided at one surface side of the substrate so that the undersurface thereof faces the through hole, and is covered with the sealing resin which is provided at the one surface side of the substrate and the through hole.

3. The module according to claim 1,
wherein the sealing resin includes first and second sealing resin portions, in which the LED chip and the wiring bodies are provided on a surface of the first sealing resin portion, and the second sealing resin portion is provided so as to embed the chip and the wiring bodies on the surface of the first sealing resin portion.

4. The module according to claim 1,
wherein the pair of wiring bodies are provided so as to be exposed to a front surface and a rear surface which are outer surfaces, of the sealing resin, respectively.

5. The module according to claim 1,
wherein the LED chip is provided so as to come into contact with the wiring bodies, and
wherein the sealing resin is provided so that the wiring bodies, or a radiating body which is connected to the wiring bodies to be able to conduct heat is exposed to an outer surface, or is protruded from the outer surface.

6. The module according to claim 1,
wherein the translucent sealing resin contains phosphor.

7. The module according to claim 1,
wherein white light is radiated due to light of the LED chip, and light of the phosphor.

8. The module according to claim 1,
wherein radiated light is output to a front side and a rear side from the LED chip.

9. The module according to claim 1,
wherein the sealing resin which covers the top surface, and the sealing resin which covers the undersurface of the LED chip are the same material as each other.

10. The module according to claim 1,
wherein the LED chips are connected in series through an intermediate wiring body, are connected in series, and in parallel by the pair of wiring bodies, and are electrically connected to the intermediate wiring body, and to the pair of wiring bodies, respectively.

11. A lighting apparatus comprising:
an LED module which includes an LED chip, a pair of wiring bodies which are connected to both electrodes of the LED chip, respectively, and light-transmissive sealing resin which covers a top surface and an undersurface of the LED chip, and covers at least a part of the pair of wiring bodies;
a main body which is arranged with the LED module; and
a power supply unit which supplies power to the LED chip of the LED module.

12. The apparatus according to claim 11, further comprising an opaque substrate including a through hole,
wherein the LED chip is provided at one surface side of the substrate so that the undersurface thereof faces the through hole, and is covered with the sealing resin which is provided at the one surface side of the substrate and the through hole.

13. The apparatus according to claim 11,
wherein the sealing resin includes first and second sealing resin portions, in which the LED chip and the wiring bodies are provided on a surface of the first sealing resin portion, and the second sealing resin portion is provided so as to embed the chip and the wiring bodies on the surface of the first sealing resin portion.

14. The apparatus according to claim 11,
wherein the pair of wiring bodies are provided so as to be exposed to a front surface and a rear surface which are outer surfaces, of the sealing resin, respectively.

15. The apparatus according to claim 11,
wherein the LED chip is provided so as to come into contact with the wiring bodies, and
wherein the sealing resin is provided so that the wiring bodies, or a radiating body which is connected to the wiring bodies to be able to conduct heat is exposed to an outer surface, or is protruded from the outer surface.
